(19) United States
(12) Patent Application Publication
(10) Pub. No.: US 2026/0098887 A1
(43) Pub. Date: Apr. 9, 2026

(54) COMPUTER SYSTEM AND METHOD FOR VOLTAGE MEASUREMENTS

(71) Applicant: VOLVO TRUCK CORPORATION, Göteborg (SE)

(72) Inventors: Rohan NEILSON, Västerås (SE); Dani BARKAH, Eskilstuna (SE); Alessandro CARNEVALI, Eskilstuna (SE)

(73) Assignee: VOLVO TRUCK CORPORATION, Göteborg (SE)

(21) Appl. No.: 19/349,273

(22) Filed: Oct. 3, 2025

(30) Foreign Application Priority Data
Oct. 4, 2024 (EP) 24204701.7

(51) Int. Cl. G01R 31/00; G01R 27/02; G01R 31/14

(52) U.S. Cl. CPC G01R 31/007; G01R 27/025; G01R 31/14

(57) ABSTRACT

A computer system comprising processing circuitry is provided. The computer system is configured to obtain a chassis voltage between a first traction voltage pole and a chassis of a vehicle; obtain a scheduled switching time to switch from the first traction voltage pole to the second traction voltage pole in order to measure the chassis voltage between the second traction voltage pole and the chassis of the vehicle; determine a disturbance on the first or second voltage pole; adjust the scheduled switching time and/or a corrective algorithm; and obtain a chassis voltage between the second traction voltage pole and the chassis of the vehicle based on the adjusted scheduled switching time and/or the corrective algorithm.

### TECHNICAL FIELD

The disclosure relates generally to electrical systems. In particular aspects, the disclosure relates to computer systems and methods for voltage measurements. The disclosure can be applied to heavy-duty vehicles, such as trucks, buses, and construction equipment, among other vehicle types. Although the disclosure may be described with respect to a particular vehicle, the disclosure is not restricted to any particular vehicle.

### BACKGROUND

Isolation resistance measurement is commonly performed in vehicles in order to determine the resistance to current leakage from a vehicle voltage bus to thechassis of the vehicle. Such measurements are typically performed by alternately connecting the positive and negative poles of the traction voltage bus of the vehicle to the chassis via known safe resistances and analyzing the relative voltage shift achieved.

Such comparative measurement is taken over two sample points with substantial stabilization time between them. Due to capacitance effects and the need to keep leakage current safely low this process takes some time. This time offset allows the possibility for values assumed to be constant to change producing erroneous output values. Running a lower switching frequency gives a good accuracy but a poor response time which can compromise safety and reduce the value of an accurate reading whereas a higher switching frequency gives the opposite problem.

Isolation resistance monitoring devices can adapt their switching frequency to an optimized value based on the observed capacitance of the system and can even further shorten the switching frequency by projecting the swing curve to a logical asymptote and cutting it short rather than waiting for it to stabilize. However, the voltage curve resulting from an isolation resistance measurement is naturally disturbed when a change occurs in the system. A good example of this is a battery contactor closing and suddenly reducing the resistance, or a pre-charge resistor redistributing the resistance. In such example an un-energized subsystem is connecting a pole and since it is now entirely leaking from this pole voltage to chassis its entire resistance appears on this pole and the floating bus moves (this pole closer to the chassis voltage). Following this a pre-charge resistor can polarize the sub-system and its resistance is then redistributed more equally between the poles and the bus begins oscillating more equally around the chassis again. Since the total isolation resistance is proportional to the peak-peak voltage, where the disturbance occurs relative to the switch sequence can have a particularly large effect on the peak-peak voltage.

Completing both actions, i.e. connection and pre-charge, within a single swing can remove the possibility of this worst-case error but has the disadvantage of risking the pre-charge sequence.

The isolation resistance monitoring device becomes temporarily uncertain, particularly on the pole not currently being measured. This significantly increases the risk for false flags and capacitance calculations and curve projections are likely to return an error or be significantly impacted.

Based on the above, there is a need for improved approaches to isolation resistance monitoring in vehicles.

### SUMMARY

According to a first aspect of the disclosure, a computer system is provided. The computer system comprises processing circuitry configured to: obtain a chassis voltage between a first traction voltage pole and a chassis of a vehicle; obtain a scheduled switching time to switch from the first traction voltage pole to the second traction voltage pole in order to measure the chassis voltage between the second traction voltage pole and the chassis of the vehicle; determine a disturbance on the first or second traction voltage pole; adjust the scheduled switching time and/or a correction algorithm; and obtain a chassis voltage between the second traction voltage pole and the chassis of the vehicle based on the adjusted scheduled switching time and/or the correction algorithm. The first aspect of the disclosure may seek to improve accuracy for isolation resistance monitoring. A technical benefit may include reducing measurement faults and errors in interpreting measurement data.

Optionally in some examples, including in at least one preferred example, the processing circuitry is further configured to determine the disturbance as a scheduled disturbance or an occurring disturbance on the first or second traction voltage pole. A technical benefit may include preventing or at least reducing measurement faults.

A component can announce its disturbance to the voltage bus and the nature of the disturbance. Isolation resistance monitoring can then elect to adapt or reset its switch timing and/or adapt its calculation, using a corrective algorithm, to correct for this. In some examples it may simply be ignored. Dependence is not required and both forward and backward compatibility are thus possible.

A disturbance may be determined from a negative contactor only, with no voltage. Such example may be realized by a fuel cell system without voltage and therefore the entire fuel cell stack is connected to negative pole voltage. Vehicle positive pole resistance is unchanged and full stack resistance appears on negative pole. Isolation resistance calculation can thus be made using a corrective algorithm, ignoring the last voltage and use last resistance from the positive voltage pole (i.e. keeping the resistance constant).

A disturbance may be determined from a pre-charge on the positive pole, while the negative contactor is closed. The total resistance is staying essentially constant and voltage movement reflects changing asymmetry. Isolation resistance calculation can thus be made using a corrective algorithm, comparing the voltage shift and use the resistance on the positive pole as being equal to the resistance on the negative pole. While the resistance can be assumed to be constant, actual transfer functions may vary. That is across such a shift it may be better to essentially project a new ”last voltage peak” and therefore ”adjusted peak-peak voltage” but the exact method may depend on the transfer function to which the adjustment is being applied.

A disturbance may be determined from a resistance decrease, expected to be symmetrical. Such example may occur when a battery is connected to the voltage bus after balancing. Component positive pole matches vehicle positive pole when negative contactor closes despite the positive pole being open (hence positive already leaks as if positive was closed). In such example a corrective algorithm may be used, setting the resistance on the positive pole as being equal to the resistance on the negative pole.

Preferably, where devices or components must make an unscheduled change, shift, or disturbance they should ideally alert the isolation resistance monitoring, allowing it to adapt its cycle, make a compensation, or make a more informed decision regarding a measurement which might have been predictably affected. Capacitance and projection optimizations may be adapted or suppressed.

The isolation resistance monitoring may opt to use these alternative assumptions and calculations based on changing conditions it detects on the bus/network (e.g. known characteristics) or more preferentially in response to being notified of such an event/change (by the component, system, or controller), the nature of this change, and potentially even further information such as the internal voltage of the component making the change.

A technical benefit is to avoid predictable transient errors allowing systems or operators to detect and respond faster to problems for a safety improvement while also being able to operate more of a ”hair trigger” due to reduced risk of false positives. It can also aid/improve calculations based on output changes of the isolation resistance monitoring.

In response to the disturbance the isolation resistance monitoring may adapt its switching. In some cases this may be to accept a value prematurely and proceed and in others to hold and take an extra or updated value and potentially evaluate this shift. A conventional approach of adaptive switching may be to wait for a low dV/dt (relatively settled voltage after capacitance charging) before switching. The dV/dt may be upset by pre-charge or other voltage shift in the connected component causing the event, the dV/dt of which causes a corresponding dV/dt not relating to capacitance. A typical outcome is that switching on one pole terminates early and on the other pole being late and often halting causing the measuring process to halt. Another example is sharp conductivity changes in fuel cell coolant which will tend to have a symmetrical effect on the dV/dt asymptote. The dV/dt may therefore be assessed relative to the dV/dt expected from the event/conditions to allow it to continue, or switching may proceed with less adaptive timing, and in more complex examples a symmetric or asymmetrical dV/dt constant may be deduced.

A technical benefit is to prevent or reduce measurement halts for safety improvement and/or better values.

Optionally in some examples, including in at least one preferred example, the processing circuitry is further configured to obtain a time request for a predicted shift of the chassis voltage occurring at the scheduled switching time. A technical benefit may include the possibility to also adjust the time request, thereby optimizing the timing of voltage measurements.

Optionally in some examples, including in at least one preferred example, the processing circuitry is further configured to: determine that the time request for the predicted shift of the chassis voltage is within a predetermined time interval relative the scheduled switching time, and adjust at least one of the scheduled switching time and the time request such that the time request for the predicted shift of the chassis voltage is outside the predetermined time interval. A technical benefit may include more robust timing, not necessarily requiring exact points in time resulting in more accurate measurements.

Optionally in some examples, including in at least one preferred example, the processing circuitry is further configured to: obtain the time request for the predicted shift of the chassis voltage by obtaining a time request for an electrical connection of a vehicle component to the first traction voltage pole. A technical benefit may include reducing the impact of load connections when monitoring the characteristics of voltage poles and their associated electrical system.

Optionally in some examples, including in at least one preferred example, the processing circuitry is further configured to: adjust at least one of the scheduled switching time and the time request by delaying the scheduled switching time. A technical benefit may include a synchronized and efficient approach to improving measurements.

Optionally in some examples, including in at least one preferred example, the processing circuitry is further configured to: adjust at least one of the scheduled switching time and the time request by delaying the electrical connection of a vehicle component to the first traction voltage pole. A technical benefit may include a synchronized and efficient approach to improving measurements.

Optionally in some examples, including in at least one preferred example, the processing circuitry is further configured to: determine a time window, and adjust at least one of the scheduled switching time and the time request by effecting the switch from the first traction voltage pole to a second traction voltage pole and/or the electrical connection of a vehicle component to the first traction voltage pole within said time window. A technical benefit may include allowing the use of pre-determined, or dynamic, time windows to effect the scheduled switching time and/or the time request.

Optionally in some examples, including in at least one preferred example, the processing circuitry is further configured to: determine that the chassis voltage is swinging; wherein the time request for the predicted shift of the chassis voltage coincides with the swinging behavior of the chassis voltage. A technical benefit may include a robust and reliable approach to decide when synchronization is needed.

Optionally in some examples, including in at least one preferred example, the processing circuitry is further configured to: switch from the first traction voltage pole to a second traction voltage pole at a non-ideal shift of the obtained chassis voltage; obtain a chassis voltage between a second traction voltage pole and the chassis of the vehicle; and correct the obtained chassis voltage between the second traction voltage pole and the chassis of the vehicle based on the non-ideal shift of the obtained chassis voltage. A technical benefit may include reducing faulty measurements and their possible impact on system monitoring.

Optionally in some examples, including in at least one preferred example, the processing circuitry is further configured to: suppress the obtained chassis voltage between the second traction voltage pole and the chassis of the vehicle based on the non-ideal shift of the obtained chassis voltage. A technical benefit may include a simple and effective approach to improve measurement accuracy and reliability.

Optionally in some examples, including in at least one preferred example, the processing circuitry is further configured to: determine an isolation resistance between the first traction voltage pole and the chassis of the vehicle based on the measured chassis voltage, and determine an isolation resistance between the second traction voltage pole and the chassis of the vehicle based on the measured chassis voltage. A technical benefit may include providing useful data for system monitoring and performance optimization and control.

Optionally in some examples, including in at least one preferred example, the processing circuitry is further configured to: determine that the time request for the predicted shift of the chassis voltage is within a predetermined time interval relative the scheduled switching time, and adjust at least one of the scheduled switching time and the time request such that the time request for the predicted shift of the chassis voltage is outside the predetermined time interval and wherein the time request is synchronized with the chassis voltage being asymptotic, or otherwise coordinated to improve measurement such as to reduce disturbance or create additional points: obtain the time request for the predicted shift of the chassis voltage by obtaining a time request for an electrical connection of a vehicle component to the first traction voltage pole; adjust at least one of the scheduled switching time and the time request by delaying the scheduled switching time; adjust at least one of the scheduled switching time and the time request by delaying the electrical connection of a vehicle component to the first traction voltage pole; determine a time window, and adjust at least one of the scheduled switching time and the time request by effecting the switch from the first traction voltage pole to a second traction voltage pole and/or the electrical connection of a vehicle component to the first traction voltage pole within said time window; determine that the chassis voltage is swinging; wherein the time request for the predicted shift of the chassis voltage coincides with the swinging behavior of the chassis voltage; switch from the first traction voltage pole to a second traction voltage pole at a non-ideal shift of the obtained chassis voltage; obtain a chassis voltage between a second traction voltage pole and the chassis of the vehicle; and suppress the obtained chassis voltage between the second traction voltage pole and the chassis of the vehicle based on the non-ideal shift of the obtained chassis voltage; and determine an isolation resistance between the first traction voltage pole and the chassis of the vehicle based on the measured chassis voltage, and determine an isolation resistance between the second traction voltage pole and the chassis of the vehicle based on the measured chassis voltage. A technical benefit may include applying an intelligent approach of identifying the chassis voltage to approaching a constant, and identifying such situation to be a reliable time for switching.

According to a second aspect of the disclosure, a vehicle is provided. The vehicle comprises the computer system of the first aspect. The second aspect of the disclosure may seek to improve accuracy for isolation resistance monitoring. A technical benefit may include optimized timing of voltage measurements, thereby reducing measurement faults and errors in interpreting measurement data.

Optionally in some examples, including in at least one preferred example, the vehicle further comprises a traction voltage bus comprising a first traction voltage pole and a second traction voltage pole, and an isolation resistance monitoring device configured to monitor the isolation resistance between the voltage bus and a chassis of the vehicle, and to selectively switch the connection between the first and second traction voltage poles. A technical benefit may include a useful, efficient, and reliable approach to obtain accurate monitoring of the isolation resistance.

According to a third aspect of the disclosure, a computer-implemented method is provided. The computer-implemented method comprises: obtaining, by processing circuitry of a computer system, a chassis voltage between a first traction voltage pole and a chassis of a vehicle; obtaining, by the processing circuitry, a scheduled switching time to switch from the first traction voltage pole to the second traction voltage pole in order to measure the chassis voltage between the second traction voltage pole and the chassis of the vehicle; obtaining, by the processing circuitry, a time request for a predicted shift of the chassis voltage occurring at the scheduled switching time; adjusting, by the processing circuitry, at least one of the scheduled switching time and the time request; and obtaining, by the processing circuitry, a chassis voltage between the second traction voltage pole and the chassis of the vehicle after the scheduled switching time. The third aspect of the disclosure may seek to improve accuracy for isolation resistance monitoring. A technical benefit may include optimized timing of voltage measurements, thereby reducing measurement faults and errors in interpreting measurement data.

Optionally in some examples, including in at least one preferred example, the method further comprises determining, by the processing circuitry, that the time request for the predicted shift of the chassis voltage is within a predetermined time interval relative the scheduled switching time, and adjusting, by the processing circuitry, at least one of the scheduled switching time and the time request such that the time request for the predicted shift of the chassis voltage is outside the predetermined time interval. A technical benefit may include more robust timing, not necessarily requiring exact points in time resulting in more accurate measurements.

Optionally in some examples, including in at least one preferred example, the method further comprises obtaining, by the processing circuitry, the time request for the predicted shift of the chassis voltage by obtaining a time request for an electrical connection of a vehicle component to the first traction voltage pole. A technical benefit may include reducing the impact of load connections when monitoring the characteristics of voltage poles and their associated electrical system.

Optionally in some examples, including in at least one preferred example, the method further comprises adjusting, by the processing circuitry, at least one of the scheduled switching time and the time request by delaying the scheduled switching time. A technical benefit may include a synchronized and efficient approach to improving measurements.

Optionally in some examples, including in at least one preferred example, the method further comprises adjusting, by the processing circuitry, at least one of the scheduled switching time and the time request by delaying the electrical connection of a vehicle component to the first traction voltage pole. A technical benefit may include a synchronized and efficient approach to improving measurements.

According to a fourth aspect of the disclosure, a computer program product is provided. The computer program product comprises program code for performing, when executed by the processing circuitry, the method of the third aspect. The fourth aspect of the disclosure may seek to improve accuracy for isolation resistance monitoring. A technical benefit may include optimized timing of voltage measurements, thereby reducing measurement faults and errors in interpreting measurement data.

According to a fifth aspect of the disclosure, a non-transitory computer-readable storage medium is provided. The non-transitory computer-readable storage medium comprises instructions, which when executed by the processing circuitry, cause the processing circuitry to perform the method of the third aspect. The fifth aspect of the disclosure may seek to improve accuracy for isolation resistance monitoring. A technical benefit may include optimized timing of voltage measurements, thereby reducing measurement faults and errors in interpreting measurement data.

According to another aspect of the disclosure, a computer system is provided. The computer system comprises processing circuitry configured to: obtain a chassis voltage between a first traction voltage pole and a chassis of a vehicle; obtain a scheduled switching time to switch from the first traction voltage pole to the second traction voltage pole in order to measure the chassis voltage between the second traction voltage pole and the chassis of the vehicle; determine a time request for a disturbance on the first or second traction voltage pole, or for a disturbance affecting the system and/or voltage balance or distribution, said disturbance occurring within a predetermined time interval relative the scheduled switching time; adjust the scheduled switching time or the time request for the disturbance such that the time request is outside the predetermined time interval; and obtain a chassis voltage between the second traction voltage pole and the chassis of the vehicle based on the adjusted scheduled switching time or the adjusted time request.

The disclosed aspects, examples (including any preferred examples), and/or accompanying claims may be suitably combined with each other as would be apparent to anyone of ordinary skill in the art. Additional features and advantages are disclosed in the following description, claims, and drawings, and in part will be readily apparent therefrom to those skilled in the art or recognized by practicing the disclosure as described herein.

There are also disclosed herein computer systems, control units, code modules, computer-implemented methods, computer readable media, and computer program products associated with the above discussed technical benefits.

### BRIEF DESCRIPTION OF THE DRAWINGS

FIG. 1 is an exemplary side view of a vehicle according to an example.

FIG. 2 is an exemplary system diagram of an electrical system comprising an isolation resistance monitoring system according to an example.

FIG. 3A is a series of diagrams showing different parameters obtained by an isolation resistance monitoring system according to an example.

FIG. 3B is an exemplary system diagram of an electrical system comprising an isolation resistance monitoring system according to one example.

FIG. 3C is a diagram showing isolation resistance monitoring of the electrical system shown in FIG. 3B over time, according to one example.

FIGS. 4A-B are diagrams showing the switching operation of an isolation resistance monitoring system according to different examples.

FIG. 5 is an exemplary system diagram of an isolation resistance monitoring system according to an example.

FIG. 6 is another view of FIG. 5, according to an example.

FIG. 7 is an exemplary system diagram of an electrical system comprising an isolation resistance monitoring system according to an example.

FIG. 8 is a flow chart of an exemplary method for voltage measurements according to an example.

FIG. 9 is a schematic diagram of an exemplary computer system for implementing examples disclosed herein, according to an example.

### DETAILED DESCRIPTION

The detailed description set forth below provides information and examples of the disclosed technology with sufficient detail to enable those skilled in the art to practice the disclosure.

The present disclosure relates to computer systems and method for isolation monitor switching. The general idea is to identify that a shift in the chassis voltage, occurring at or close to a switch between which traction voltage pole is being monitored, will cause a disturbance that possibly will interfere with the isolation resistance monitoring leading to false or non-valid measurements. By adapting the calculation to reflect the assumptions which hold valid under the conditions, by making adjustments for predictable disturbances, and by modifying switching sequences and even the timing of the events themselves, the examples presented herein can reduce isolation resistance monitoring disturbance. The performance of diagnostic methods can be improved and additionally such diagnostic method will become more compatible with frequency shortening methods. This should deliver more safe and reliable systems and methods.

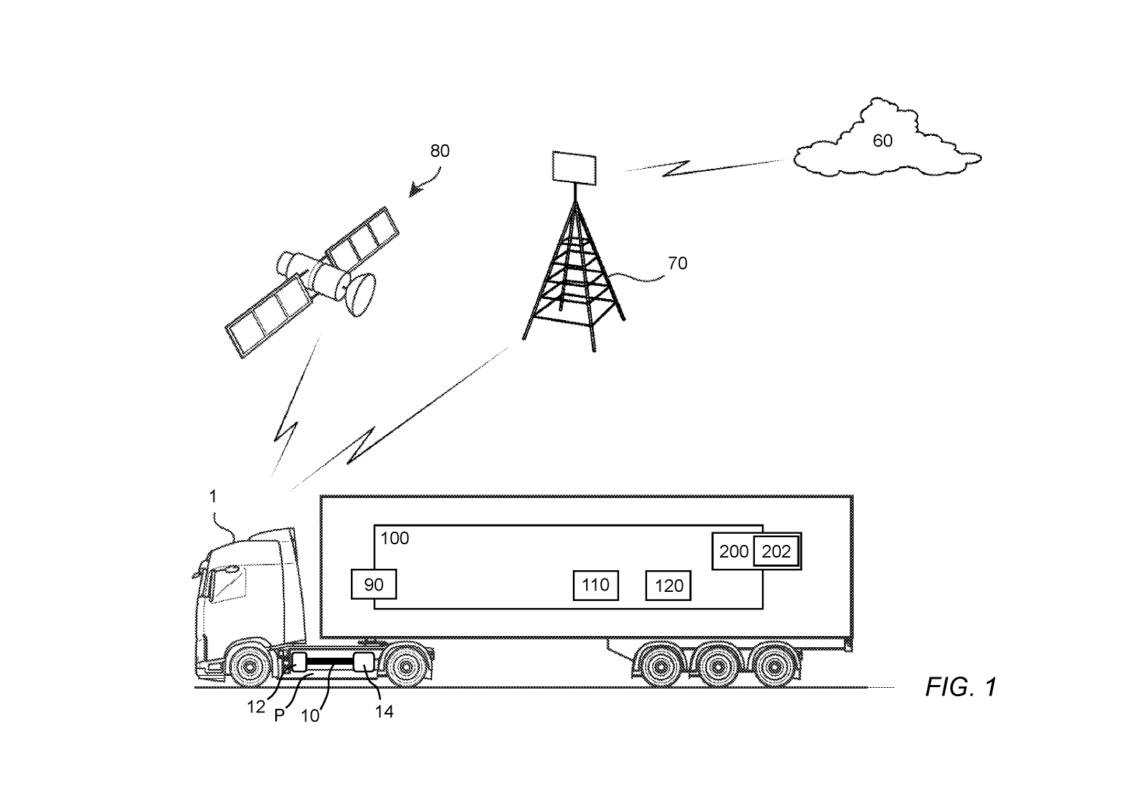

FIG. 1 is an exemplary side view of a vehicle 1 according to an example. The vehicle 1 comprises at least one isolation resistance monitoring system 200. The at least one isolation resistance monitoring system 200 is configured to determine the electrical isolation resistance between a traction voltage bus 10 and a chassis P of the vehicle 1, and to control how and when the isolation resistance is determined. Typically, the traction voltage bus 10 is provided to distribute electrical power from an energy storage system 12, such as a battery or a fuel cell system, to one or more electrical loads such as one or more electrical traction motors 14. The vehicle 1 is programmed to control the isolation resistance monitoring system 200, as will be described further in the following.

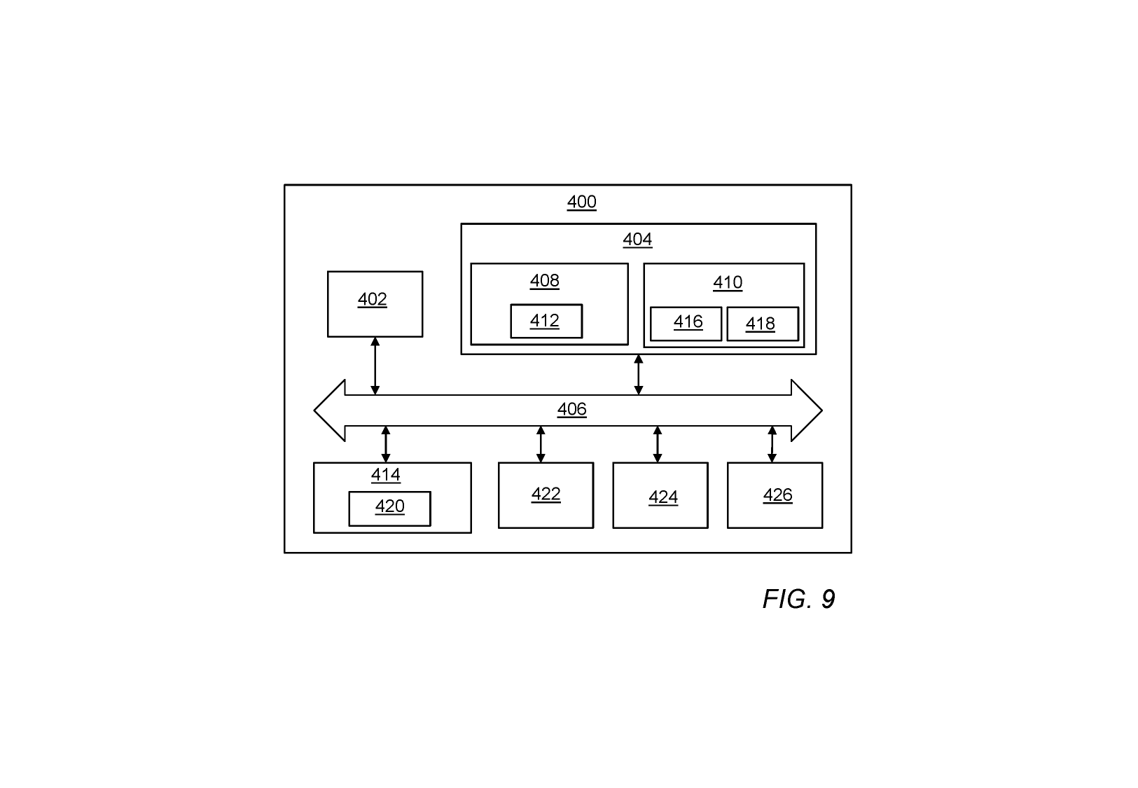

The vehicle 1 comprises, at least to some extent, processing circuitry 110 forming part of a computer system 100 (see FIG. 9). The processing circuitry 110 is configured to implement the isolation resistance monitoring system 200.

The vehicle 1 may further comprise communications circuitry 90 configured to receive and/or send communications. The communications circuitry 90 may be configured to enable the vehicle 1 to communicate with one or more external devices or systems such as a cloud server 60. The communication with the external devices or systems may be directly or via a communications interface such as a cellular communications interface 70, such as a radio base station. The cloud server 60 may be any suitable cloud server exemplified by, but not limited to, Amazon Web Services (AWS), Microsoft Azure, Google Cloud Platform (GCP), IBM Cloud, Oracle Cloud Infrastructure (OCI), DigitalOcean, Vultr, Linode, Alibaba Cloud, Rackspace etc. The communications interface may be a wireless communications interface exemplified by, but not limited to, Wi-Fi, Bluetooth, Zigbee, Z-Wave, LoRa, Sigfox, 2G (GSM, CDMA), 3G (UMTS, CDMA2000), 4G (LTE), 5G (NR) etc. The communication circuitry 90 may, additionally or alternatively, be configured to enable the vehicle 1 to be operatively connected to a Global Navigation Satellite System (GNSS) 80 exemplified by, but not limited to, global positioning system (GPS), Globalnaya Navigatsionnaya Sputnikovaya Sistema (GLONASS), Galileo, BeiDou Navigation Satellite System, Navigation with Indian Constellation (NavIC) etc. The vehicle 1 may for example be configured to utilize data obtain from the GNSS 80 to determine a geographical location of the vehicle 1.

The vehicle 1 in FIG. 1 comprises the computer system 100 and the isolation resistance monitoring system 200. The computer system 100 may be operatively connected to the isolation resistance monitoring system 200 and optionally to the communications circuitry 90 of the vehicle 1. The computer system 100 comprises processing circuitry 110. The computer system 100 may comprise a storage device 120, advantageously a non-volatile storage device such as a hard disk drives (HDDs), solid-state drives (SSDs) etc. In some examples, the storage device 120 is operatively connected to the computer system 100. The isolation resistance monitoring system 200 may comprise isolation resistance monitoring system processing circuitry 202; the isolation resistance monitoring system processing circuitry 202 may be part of the processing circuitry 110 of the computer system 100.

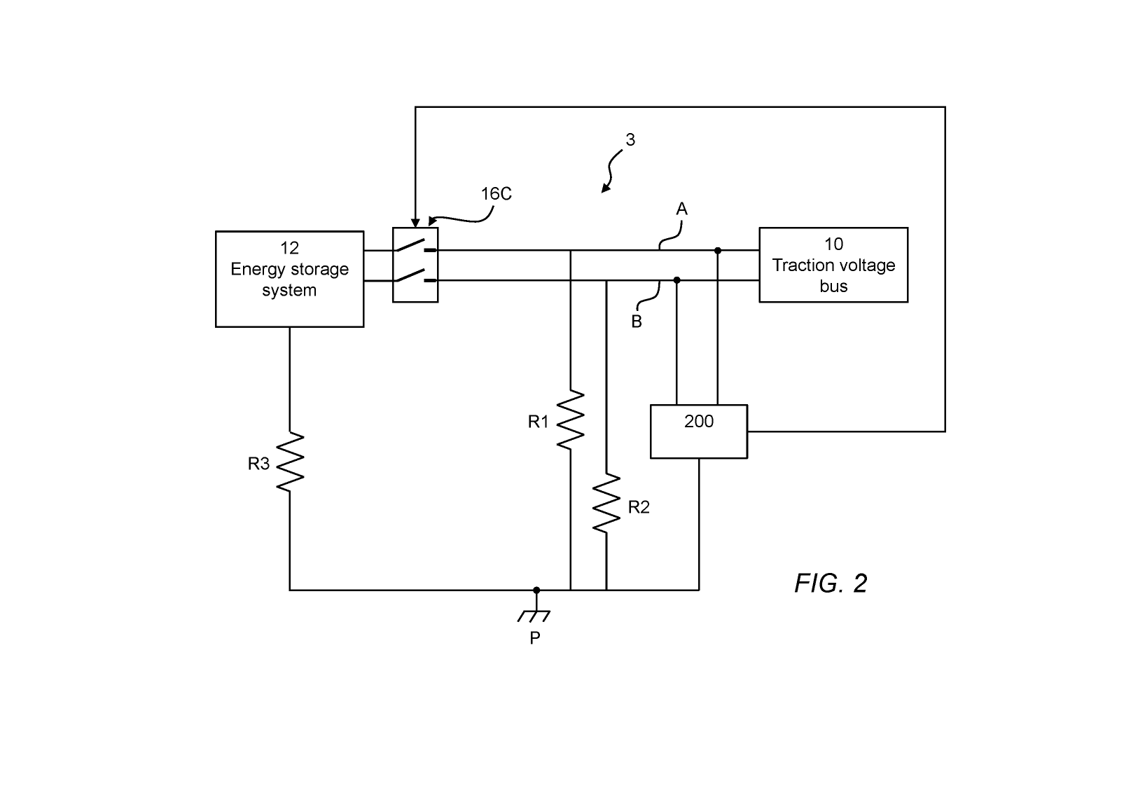

FIG. 2 is an exemplary schematic view of an electrical system 3 of an at least partly electrically driven vehicle 1, being monitored by an isolation resistance monitoring system 200.

The electrical system 3 comprises a traction voltage bus 10 being connected to and receiving or delivering power to an electrical energy system 12, such as a battery, a fuel cell system, a supercapacitor, or a load device. Typically, the energy storage system 12 connects to the traction voltage bus 10. The traction voltage bus 10 has a positive pole A and a negative pole B. Further, the energy storage system 12 may be connected to the traction voltage bus 10 via switchable contactors 18.

As is further shown in FIG. 2, the energy storage system 12 may be connected to ground P via a resistance R3. For example, in examples where the energy storage system 12 is a fuel cell system the resistance R3 may comprise a pump and/or a radiator, etc.

The total resistance between the traction voltage bus 10 and the chassis P of the vehicle 1 is represented by the resistances R1, R2 to which resistance R3 will be added when contactors 18 close.

The isolation resistance monitoring system 200 is configured to measure these resistances R1, R2. This can be done in many different ways, for example by measuring a voltage drop across a test resistor that is connected between one of the poles A, B and the chassis P of the vehicle 1.

Hence, in an attempt to minimize this risk of electric shock by implementing the isolation resistance monitoring system 200, the voltage drop between the positive terminal A of the energy storage system 12 and the chassis P and the voltage drop between the negative terminal B of the energy storage system 12 and the chassis P are subsequently measured. Each of these measurements is made after a period of time has elapsed, allowing for the voltage in the circuit to stabilize following the connection of e.g. the test resistor. This is typically due to an RC time constant, which is caused by the test resistor and the suppression and parasitic capacitors present within the system.

The settling (or decay of the voltage change) to steady state is characterized by a very long time constant, typically at least a few seconds to settle on a single asymptote. Ten to fifteen seconds is typical for a complete cycle, with five to seven seconds to settle on each asymptote. The time constant can be attributed to the combined effect of the electromagnetic compatibility suppression filter capacitors, the parasitic capacitance between the chassis P and the high voltage positive and negative terminals A, B, and the large resistance value typically employed for the test resistor. It is therefore imperative that a sufficiently lengthy interval be allowed to elapse following the connection of the test resistor before undertaking a voltage measurement, in order to ensure the accuracy of the results.

As will be further explained in the following, action on the traction voltage bus 10 may affect the voltage between the poles A, B and the chassis P. Such action may for example by the contactors 18 opening or closing. Another effect may be the level of polarisation in system 12 which will affect how R3 is distributed. Another affect may be temperature/coolant conductivity which may affect the magnitude of R3. Subsystems in 12 may also be a factor affecting R3. Changes to R1 or R2 are seen as local incidences of the invention. Change in A-B voltage will also affect A-P and B-P voltage. Due to this interference, the isolation resistance monitoring system 200 is communicating with components that may have this effect. In the shown example the isolation resistance monitoring system 200 is connected to the contactors 18, however the communication may be with any vehicle component directly or indirectly being responsible for the control of any electrical component that may affect the voltage drop.

Especially, the isolation resistance monitoring system 200 is configured to apply a switching between the first traction voltage pole A and the second traction voltage pole B at some switching frequency. The isolation resistance monitoring system 200 is further configured to receive or obtain information alerting it that an event expected to disturb isolation resistances and/or pole-to-chassis voltages has occurred or is expected to occur and ideally also the nature of the event, pole(s) affected, and preferably the voltage or the expected or internally measured resistance attached to this event. It may also be configured to adjust the assumptions made in its internal processes/calculation to suit in addition to being configured to potentially adjusting switching strategy/frequency. If this predicted or estimated chassis voltage shift is expected to disturb the chassis voltage, the timing of the switch and/or the voltage shift is adjusted such that any disturbance is avoided. Receiving and acting on event information (also internal detection of the same information) is about resolving transient deviations between the actual conditions and the assumptions normally being used in the isolation resistance monitoring and can also include some means to minimize some disturbance. For example, transient deviation is an event occurring within the alternating two-point-two-measurement cycle and hence unavoidable. Responsive adjustment of isolation resistance monitoring switching (whether external info or internal detection) is about minimizing the effect of disturbances but does not address the transient deviation issue. Scheduling of events or isolation resistance monitoring switching can essentially avoid disturbance but again does not address the transient deviation issue.

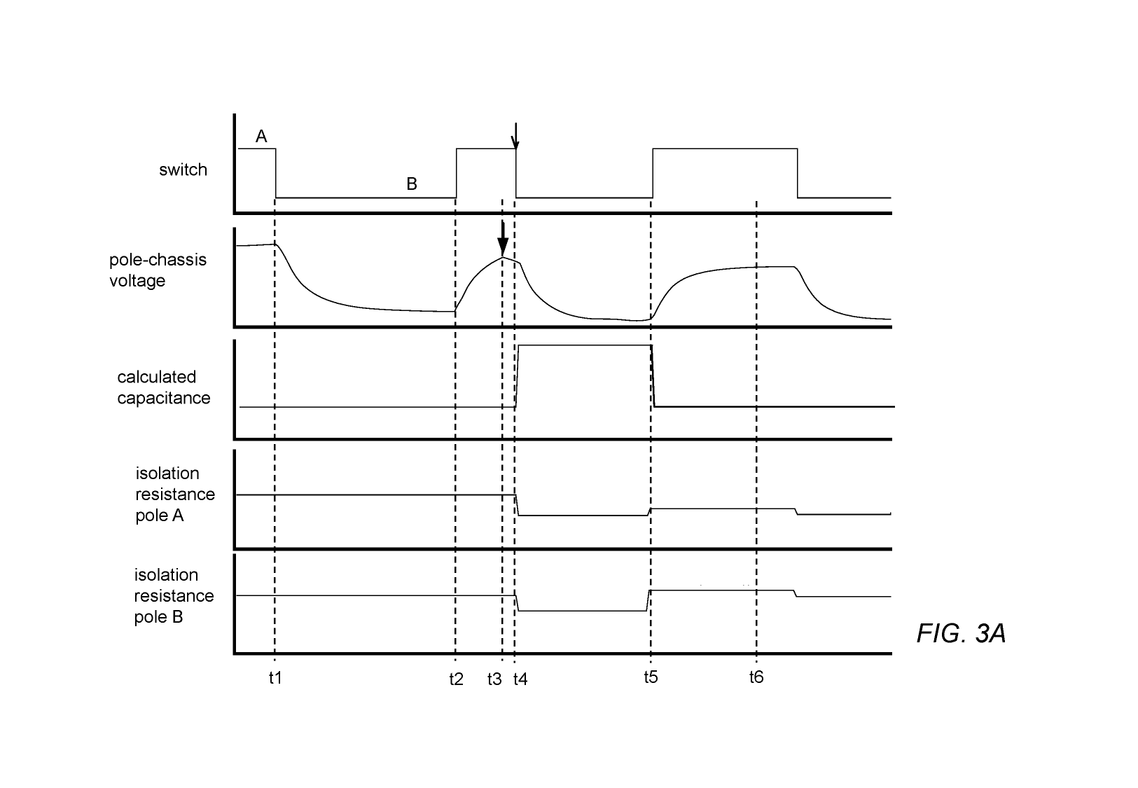

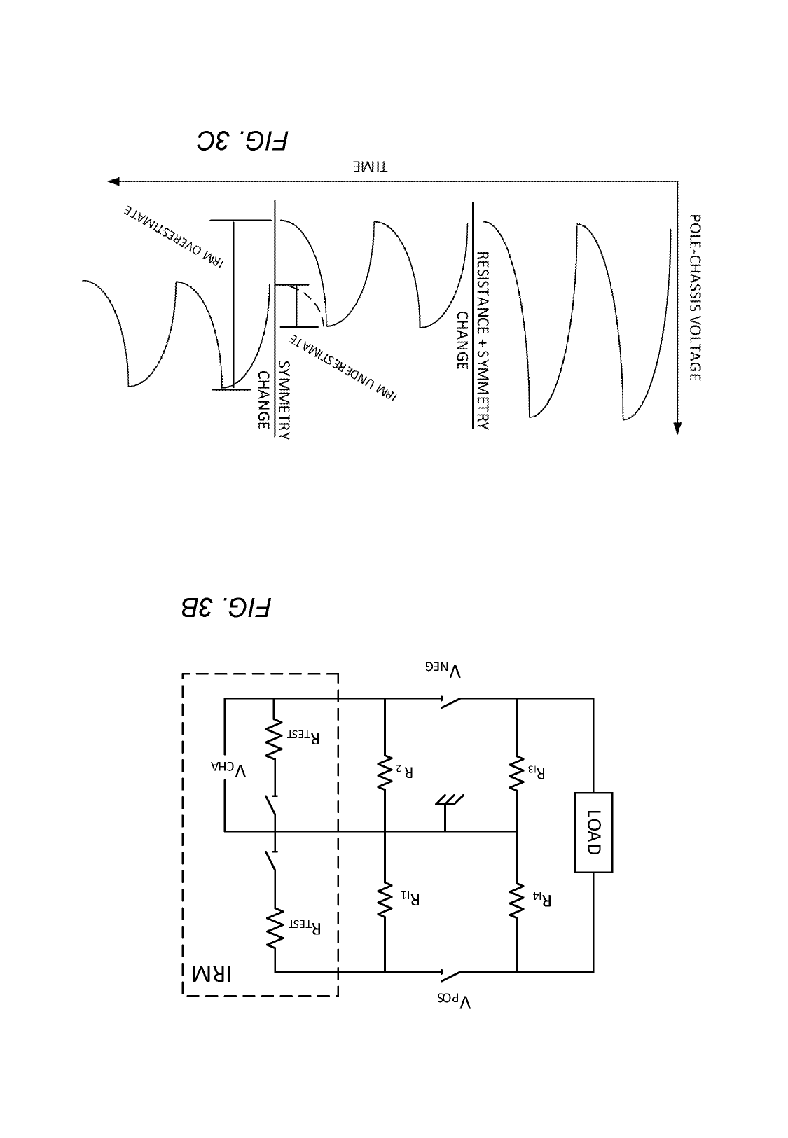

FIG. 3A shows a series of charts illustrating an exemplary sequence of measurements by an isolation resistance monitoring system 200. The top diagram shows the switching sequence between the first traction voltage pole A and the second traction voltage pole B.

The next diagram shows a pole-chassis voltage, i.e. A-P or B-P differential, being measured by the isolation resistance monitoring system 200.

The next diagram is showing a capacitance calculated by the isolation resistance monitoring system 200, and the bottom two diagrams show the calculated isolation resistance between the first traction voltage pole A and the chassis P, and between the second traction voltage pole B and the chassis P, respectively.

At time t1, the isolation resistance monitoring system 200 switches from the first traction voltage pole A to the second traction voltage pole B. The chassis voltage will start to drop slowly, while the values of the capacitance and the isolation resistances are not updated. The chassis voltage will continue to drop until it reaches an asymptotic condition towards the correct voltage level. At time t2 the isolation resistance monitoring system 200 switches from the second traction voltage pole B to the second traction voltage pole A. The measured chassis voltage will start to increase towards the previous level, while the values of the capacitance and the isolation resistances are not updated. However at time t3, a sudden action affecting the resistance between the first traction voltage pole A and chassis P only causes the measured chassis voltage to depart from its increasing behavior and instead start to drop slightly, while the values of the capacitance and the isolation resistances are not updated. At time t4, shortly after time t3, another switching occurs to the second traction voltage pole B. This early switching is due to the non-characteristic behavior of the pole-chassis voltage vs time curve tending toward zero early, indicating an early settling of the value and potentially causing an irrelevant value to be selected (a cause of disturbance error) if so extreme as to cause the curve reverse unexpectedly as shown. As this no longer adheres to the characteristic curve of a capacitor. Hence the capacitance calculation may fail, leading to a wrong, undefined or out of range value of the capacitance. A calculation of resistance based on the voltage at t2 (deviant from assumption) and that at t3 (disturbed) (or t4) indicates that total isolation resistance (proportional to the peak-peak amplitude of the pole-chassis voltage) has diminished significantly and while the symmetry (proportional to average pole-chassis voltage) can not move enough to project this onto pole A resistance alone. When t5 measurement arrives and replaces t2 in the calculation the total resistance improves, but to an over-estimate since t3 was disturbed and taken above the asymptote at t6. The drop in t5 vs t2 largely fixes the symmetry (though t3 limits this). At t6 an accurate measurement results since t5 and t6 are both clear of the event.

In order to avoid situations as described above, the isolation resistance monitoring system 200 is configured to operate an alternate process upon receiving information from another system advising of the change it has made, more specifically in this example that resistance A-P has been changed and B-P has not which allows a calculation assuming the resistance B-P from t2 holds (instead of the voltage from t2 which is now inconsistent).

Furthermore, the isolation resistance monitoring system 200 may be configured to apply an improved strategy between the switching of first/second traction voltage poles A, B to avoid the wrong voltage being detected/assigned at the disturbance t3 and furthermore arbitration strategies may be applied where it is possible to ensure a safe and optimized synchronization of events and communications and switch events to facilitate valid assumptions and the avoidance or minimization of disturbances.

In FIG. 3B another example of an electrical system is shown and in FIG. 3C an example of an isolation resistance monitoring sequence for such electrical system is shown. Basically the isolation resistance monitoring system is measuring by comparison of a series of maxima and minima with many variables assumed constant and a better outcome is obtained if which variables are assumed to be constant are changed, when the default assumption is known to be temporarily invalid and how to correct it is also known. Such errors can further be minimized by adapting the scheduling/synchronization and the two approaches can also be complementary. Similarly, if knowingly changed variables are accounted for calculations can be improved.

Generally, by adapting the algorithm for isolation resistance monitoring to reflect the current situation or best information available it is possible to largely prevent the error that appears during disruptions.

Where a system regularly moves between states timing can be of use with or without algorithm adaption. Again with reference to FIG. 3B, first the negative contactor closes and the entire “load” subsystem moves to the negative pole. All of its leakages then occur from the negative pole voltage so the entire resistance appears on the negative pole. This causes the total resistance to drop as if both contactors closed but with a heavy symmetry change since only the negative pole is affected. Secondly at right a pre-charge occurs, polarizing the load, and the positive contactor closes. Since the load is already coupled the total resistance doesn’t change but a symmetry change occurs as the resistance is redistributed into a more normal state of leakage from each pole to chassis. During each of these shifts/events/disturbances the timing between the measurement sequences and these events dictates which of the possible maxima and minima get used to calculate the isolation resistance. Since the normal calculation assumes that R1 and R2 are constant during the measurement sequence a value pair is generated which explain the observation but under an assumption that is temporarily not true. This results in unpredictable outputs but with predictably wrong values.

Here algorithm adaption can be applied. In the first event, the “RESISTANCE + SYMMETRY CHANGE” at left occurs when the negative contactor closes and all of the “LOAD” systems isolation resistance joins the negative pole. The positive pole resistance remains R1 alone so it is not expected to change. Rather than incorrectly assume the negative pole resistance stays constant through this sequence (while R3 and R4 join R2) the prior value for R1 can be re-used allowing the two different resistance cases occurring on the negative pole to be solved for from the current measurement pair. Similarly for the event at right, a “SYMMETRY CHANGE” caused by polarizing an already connected resistance, the total resistance can be re-used and the measurement pair used to calculate the re-distribution of this resistance.

As a simple example with timing adjustment only: the non-adaptive IRM will predictably either over-estimate or under-estimate depending on where in the sequence the change occurs. Since it is known that the isolation resistance is not changing, just the symmetry, it is possible to schedule for the over-estimate case to avoid false positive isolation warnings from the “blind” IRM device.

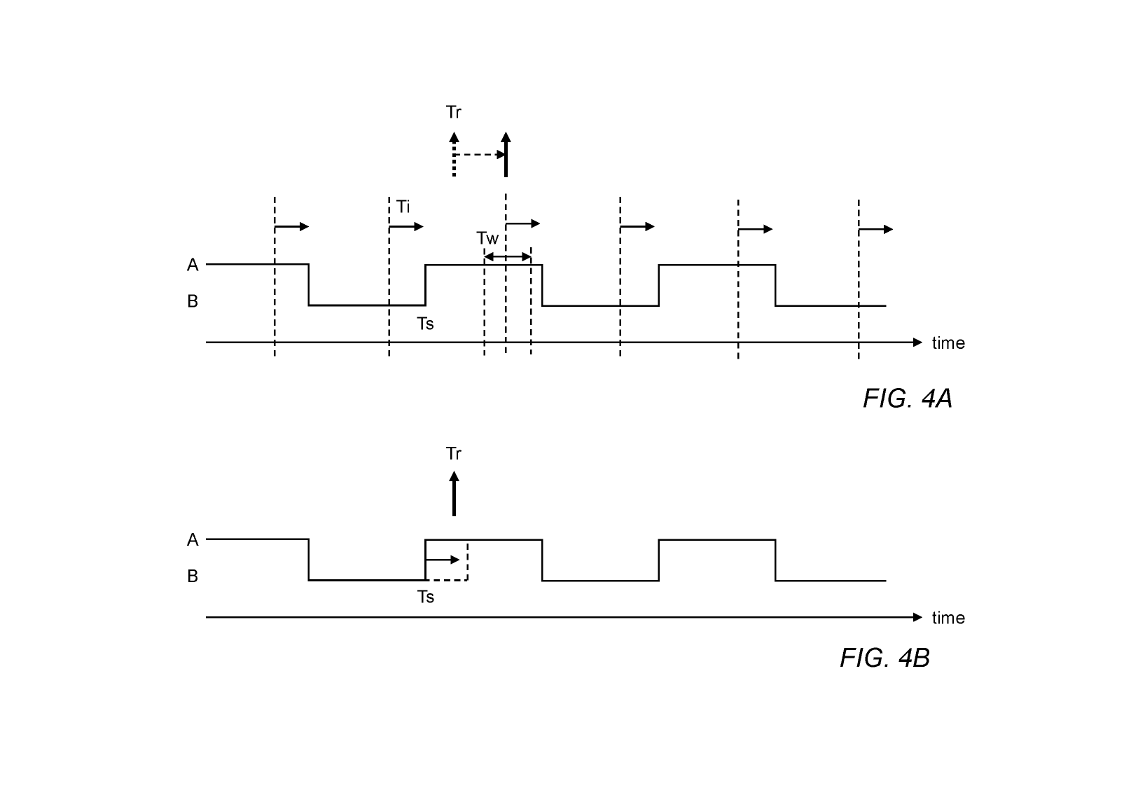

FIG. 4A is a diagram showing examples of the methodology applied by an isolation resistance monitoring system 200 according to one example. The solid square wave represents which of the first and second traction voltage poles A, B being switched on. As can be seen, initially the chassis voltage is measured against the first traction voltage pole A and is thereafter changed to the second traction voltage pole B. The voltage across at least two of the three poles A-B, A-P, B-P is measured or otherwise known and monitored (so voltage division can be assessed and because V A-B = V A-P + V B-P). Since V A-B (i.e. the actual traction voltage) is pretty core it is usually this against one of the other pairs. The voltage measurement is not switched but which pole is being connected to ground via a known resistance is. The time Ts represents a scheduled switching time from voltage traction pole B to traction voltage pole A. Time Tr represents an expected shift on the chassis voltage. The expected shift Tr may be determined based on control data from any suitable component of the vehicle 1, such as a battery management system requesting contactors to open or close, etc. The most applicable example may be something repeatable and non-consequential like another test circuit or dummy leakage being used to discern a subset of resistances from the wider network, although contactors could be relevant as an example. A further parameter Ti represents a time interval, or time window, during which it is assumed to be possible to handle a shift on the chassis voltage without it causing any disturbance to measurements on chassis voltage, capacitance, or isolation resistance on any of the poles A, B. Typically, the time window Ti begins when the chassis voltage is exhibiting an asymptotic behavior. In the shown example, the expected shift Tr is outside the time interval Ti.

In the shown example, the isolation resistance monitoring system 200 is configured to adjust the requested shift time Tr by postponing it until a time that is inside the next time interval Ti.

In FIG. 4A a further parameter, a time window Tw, is indicated. The time window Tw may represent a maximum allowed time span for delaying the scheduled switching time Ts and/or the time request Tr.

In FIG. 4B another example is shown. The normal switching sequence of the traction voltage poles A, B is shown in solid lines. The requested shift on the chassis voltage is expected to occur shortly after a switching action, which would likely cause an undesired disturbance on the monitoring. In response, the isolation resistance monitoring system 200 is configured to adjust the switching sequence such that a current switching period is extended, as indicated by the dashed lines. Hence, the requested shift on the chassis voltage, indicated by time Tr, is occurring at the end of the switching period where the chassis voltage likely exhibits the desired asymptotic behavior.

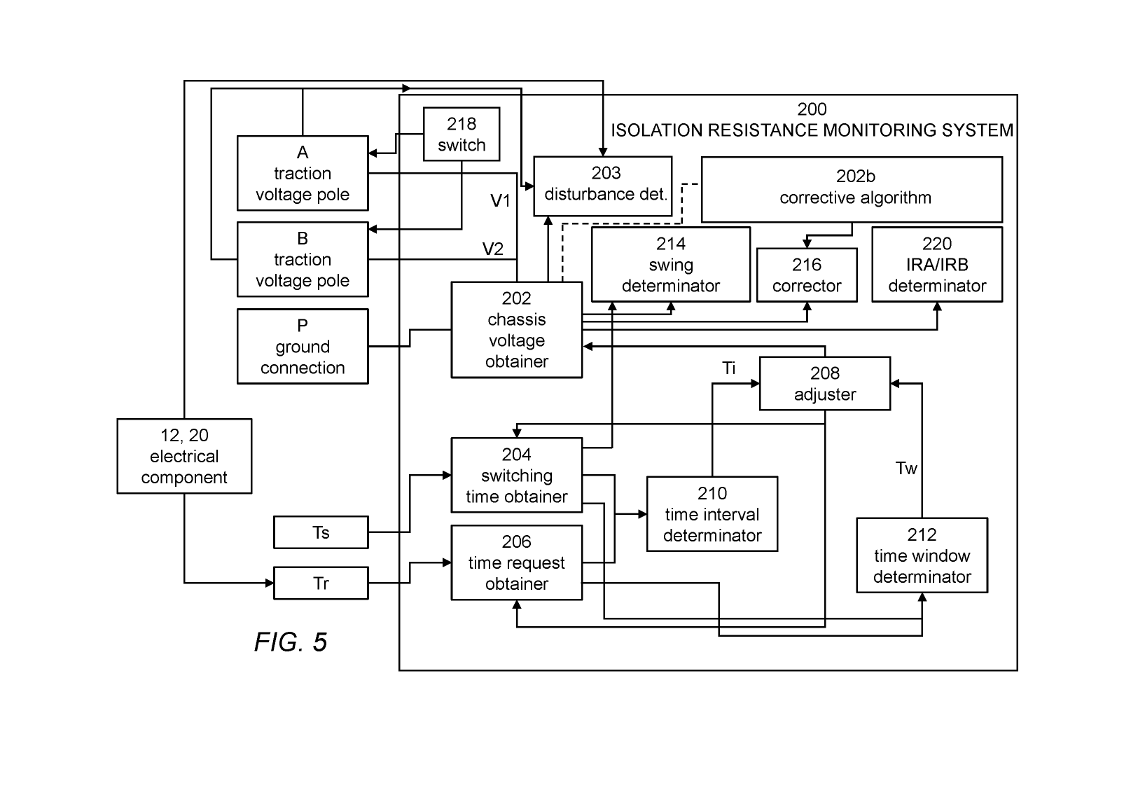

In FIG. 5 an example of an isolation resistance monitoring system 200 is schematically shown. The isolation resistance monitoring system 200 comprises a chassis voltage obtainer 202. The chassis voltage obtainer 202 is configured to obtain a chassis voltage V1 between a first traction voltage pole A and a chassis P of a vehicle 1. The isolation resistance monitoring system 200 further comprises a switching time obtainer 204. The switching time obtainer 204 is configured to obtain a scheduled switching time Ts to switch from the first traction voltage pole A to the second traction voltage pole B in order to measure a chassis voltage V2 between the second traction voltage pole B and the chassis P of the vehicle 1.

The isolation resistance monitoring system 200 comprises a disturbance determinator 203. The disturbance determinator 203 is configured to determine a disturbance, i.e. a shift, on the chassis voltage between any of the poles A, B. The disturbance may be an occurring disturbance or a scheduled disturbance, i.e. the disturbance determinator 203 may receive data from the chassis voltage obtainer 202 representing information that a disturbance has occurred, or the disturbance determinator 203 may receive data from any associated component or hardware (such as an electrical component 20) that a disturbance is about to happen. Preferably, such data is also comprising data of the expected timing of the disturbance, i.e. a time request as will be further explained below.

The chassis voltage obtainer 202 is further configured to determine and/or adjust corrective algorithm 202b based on the determined disturbance. The corrective algorithm 202b is preferably based on the obtained voltage and/or the determined disturbance. Typically, the corrective algorithm 202b is selected as one of i) adapt calculation of chassis voltage, ii) adapt switch timing, iii) request delay or adjust timing of disturbance, or iv) neglect disturbance.

The isolation resistance monitoring system 200 comprises a time request obtainer 206. The time request obtainer 206 is configured to obtain a time request Tr for a predicted shift (or disturbance) of the chassis voltage V1, V2 occurring at the scheduled switching time Ts. The time request obtainer 206 is specifically configured to obtain the time request Tr for an electrical connection of a vehicle component to the traction voltage pole A, B. Further, the isolation resistance monitoring system 200 comprises an adjuster 208. The adjuster 208 is configured to adjust the timing of at least one of the scheduled switching time Ts and the time request Tr.

The chassis voltage obtainer 202 is further configured to obtain the chassis voltage V2 between the second traction voltage pole B and the chassis P of the vehicle 1 after the scheduled switching time Ts, preferably by applying the corrective algorithm. Hence, the chassis voltage V2 will be obtained after the scheduled switching time Ts and/or the timing of the scheduled shift of the chassis voltage has been adjusted, or at the initial timings but using the corrective algorithm 202b.

The isolation resistance monitoring system 200 further comprises a time interval determinator 210. The time interval determinator 210 is configured to determine that the time request Tr for the predicted shift of the chassis voltage V1 is within a predetermined time interval Ti relative the scheduled switching time Ts. Based on this, the adjuster 208 is configured to adjust at least one of the scheduled switching time Ts and the time request Tr such that the time request Tr for the predicted shift of the chassis voltage V1 is outside the predetermined time interval Ti.

The adjuster 208 is configured to adjust at least one of the scheduled switching time Ts and the time request Tr by delaying the scheduled switching time Ts, and/or by delaying the electrical connection of a vehicle component 12, 20 to the traction voltage pole A , B.

The isolation resistance monitoring system 200 further comprises a time window determinator 212. The time window determinator 212 is configured to determine a time window Tw. Based on the determined time window Tw, the adjuster 208 is configured to adjust at least one of the scheduled switching time Ts and the time request Tr by effecting the switch from the first traction voltage pole A to a second traction voltage pole B and/or the electrical connection of a vehicle component to the first traction voltage pole A within said time window Tw. Hence, the time window Tw may represent a maximum allowed time span for delaying the scheduled switching time Ts and/or the time request Tr. The time window Tw may for example be determined based on the normal switching frequency of the isolation resistance monitoring system 200.

The isolation resistance monitoring system 200 may further comprise a swing determinator 214. The swing determinator 214 is configured to determine that the chassis voltage V1 is swinging, which may correspond to the chassis voltage V1 departing from a normal, or ideal, behavior. Further, the swing determinator 214 may be configured to determine that the scheduled switching time Ts of the chassis voltage coincides with the swinging behavior of the chassis voltage V1.

The isolation resistance monitoring system 200 may further comprise a corrector 216. The corrector 216 is configured to apply a correction factor to the obtained chassis voltage V2. For such example, the isolation resistance monitoring system 200 comprises a switch 218 configured to switch from the first traction voltage pole A to the second traction voltage pole B at a non-ideal shift of the obtained chassis voltage V1. After obtaining the chassis voltage V2 between the second traction voltage pole B and the chassis P of the vehicle 1, the corrector 216 is configured to correct the obtained chassis voltage V2 between the second traction voltage pole B and the chassis P of the vehicle 1 based on the non-ideal shift of the obtained chassis voltage V1. In some examples, the corrector 216 is configured to suppress the obtained chassis voltage V2 between the second traction voltage pole B and the chassis P of the vehicle 1 based on the non-ideal shift of the obtained chassis voltage V1. The corrector 216 may preferably operate by applying the selected corrective algorithm 202b.

The isolation resistance monitoring system 200 further comprises an isolation resistance determinator 220. The isolation resistance determinator 220 is configured to determine an isolation resistance IRA between the first traction voltage pole A and the chassis P of the vehicle 1 based on the measured chassis voltage V1, and to determine an isolation resistance IRB between the second traction voltage pole B and the chassis P of the vehicle 1 based on the measured chassis voltage V2.

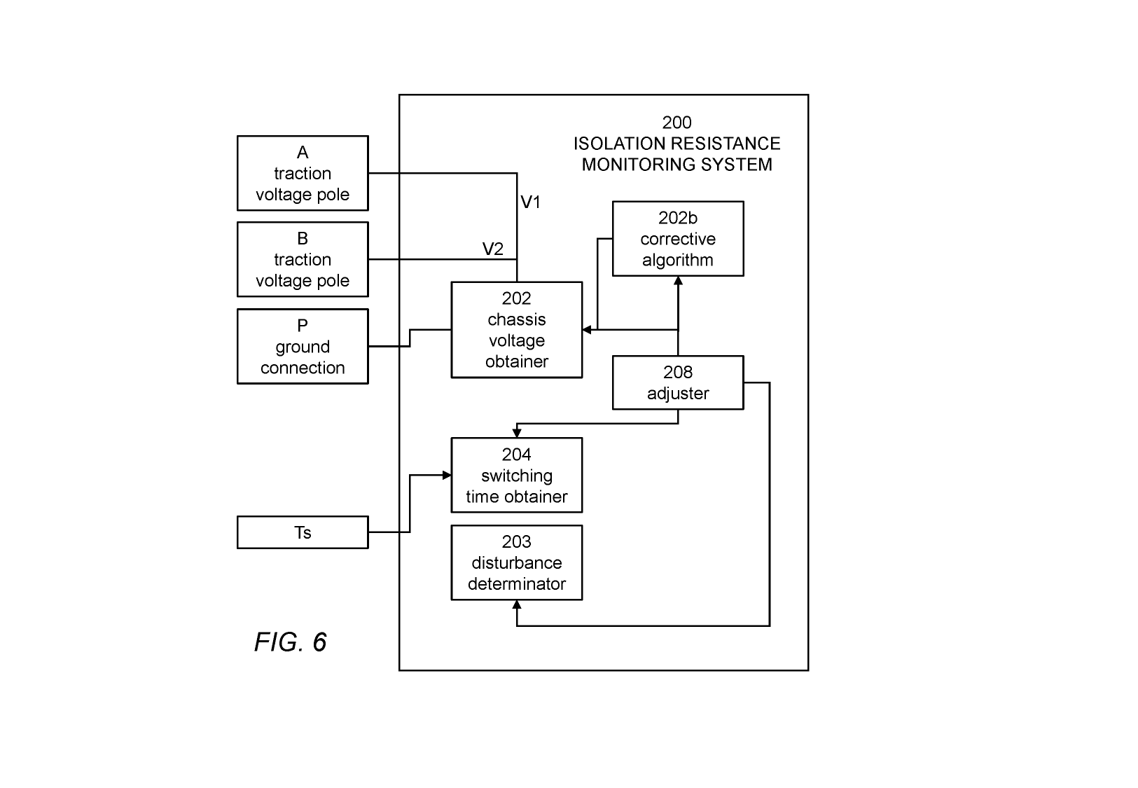

In FIG. 6 an example of an isolation resistance monitoring system 200 is schematically shown. The isolation resistance monitoring system 200 comprises a chassis voltage obtainer 202. The chassis voltage obtainer 202 is configured to obtain a chassis voltage V1 between a first traction voltage pole A and a chassis P of a vehicle 1. The isolation resistance monitoring system 200 further comprises a switching time obtainer 204. The switching time obtainer 204 is configured to obtain a scheduled switching time Ts to switch from the first traction voltage pole A to the second traction voltage pole B in order to measure a chassis voltage V2 between the second traction voltage pole B and the chassis P of the vehicle 1.

The isolation resistance monitoring system 200 comprises a disturbance determinator 203. The disturbance determinator 203 is configured to determine a disturbance, i.e. a shift, of the chassis voltage V1, V2. Further, the isolation resistance monitoring system 200 comprises an adjuster 208. The adjuster 208 is configured to adjust the timing of the scheduled switching time Ts and/ or a corrective algorithm 202b.

The chassis voltage obtainer 202 is further configured to obtain the chassis voltage V2 between the second traction voltage pole B and the chassis P of the vehicle 1 based on the adjusted switching time Ts and/or the corrective algorithm 202b. Hence, the chassis voltage V2 will be obtainer after the scheduled switching time Ts has been adjusted, and/or after applying the corrective algorithm.

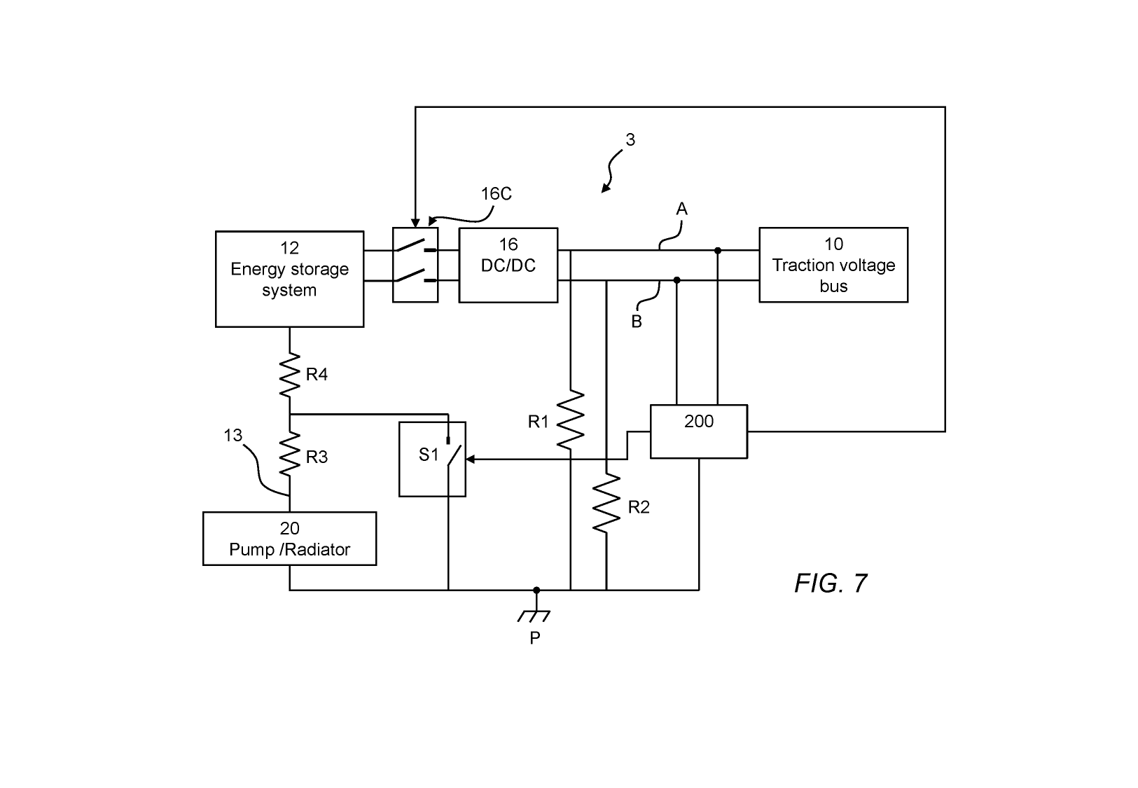

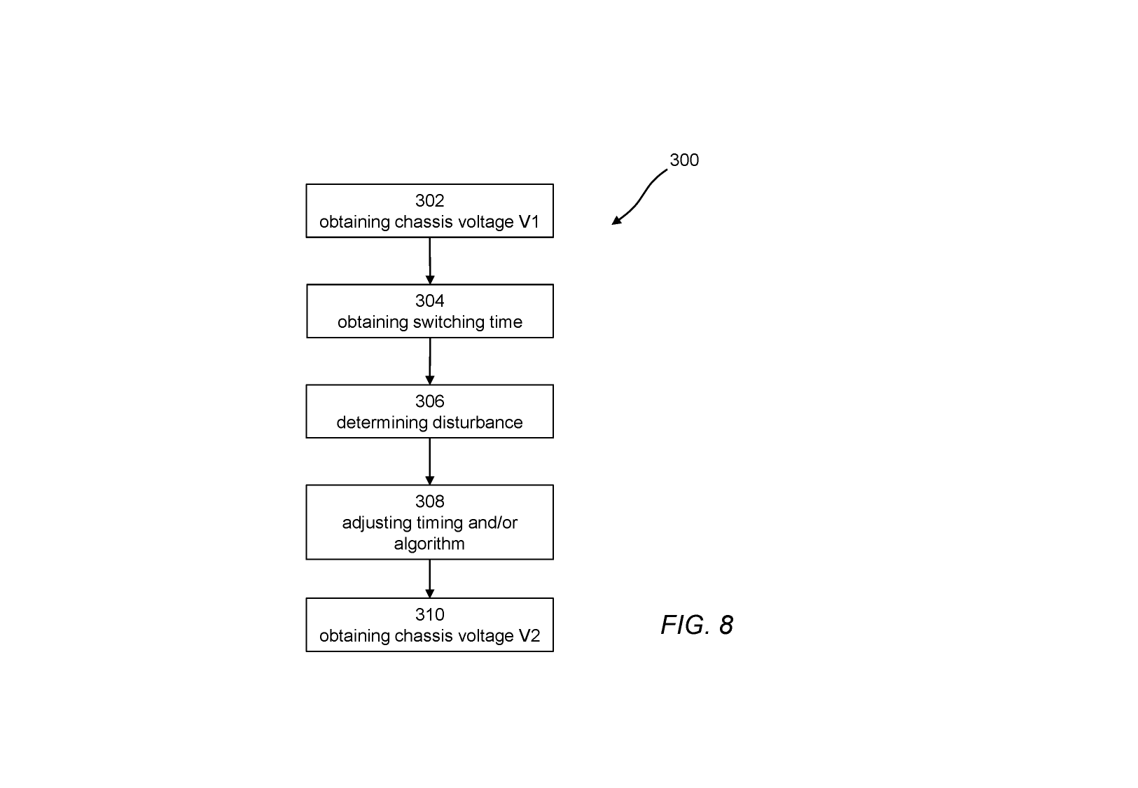

FIG. 7 shows a further example of an electrical system 3 having an isolation resistance monitoring system 200. In the shown example, a fluid conduit 13 providing electrical resistance along its length is selectively partially short circuited through a switch S1. Proportionality of the path may be used to determine the contribution of the path to the measured total and from this discern the conductivity of the fluid inside the fluid conduit 13. As timing of the operation of the switch 13 may cause the measured voltage V A-P, V B-P to depart from its ideal behavior, the isolation resistance monitoring system 200 may be configured to synchronize the operation of the switch S1 based on how the switching will affect the chassis voltage V A-P, V B-P.

In FIG. 8 a method 300 for monitoring an electrical system 3 is shown. The method 300 comprises obtaining 302, by processing circuitry of a computer system, a chassis voltage between a first traction voltage pole and a chassis of a vehicle. The method 300 further comprises obtaining 304, by the processing circuitry, a scheduled switching time to switch from the first traction voltage pole to the second traction voltage pole in order to measure the chassis voltage between the second traction voltage pole and the chassis of the vehicle. The method 300 comprises determining 306, by the processing circuitry, a disturbance on the first or second voltage pole and adjusting 308, by the processing circuitry, the scheduled switching time and/or a corrective algorithm. The method 300 further comprises obtaining 310, by the processing circuitry, a chassis voltage between the second traction voltage pole and the chassis of the vehicle based on the adjusted scheduled switching time and/or the corrective algorithm.

FIG. 9 is a schematic diagram of a computer system 400 for implementing examples disclosed herein. The computer system 400 is adapted to execute instructions from a computer-readable medium to perform these and/or any of the functions or processing described herein. The computer system 400 may be connected (e.g., networked) to other machines in a LAN (Local Area Network), LIN (Local Interconnect Network), automotive network communication protocol (e.g., FlexRay), an intranet, an extranet, or the Internet. While only a single device is illustrated, the computer system 400 may include any collection of devices that individually or jointly execute a set (or multiple sets) of instructions to perform any one or more of the methodologies discussed herein. Accordingly, any reference in the disclosure and/or claims to a computer system, computing system, computer device, computing device, control system, control unit, electronic control unit (ECU), processor device, processing circuitry, etc., includes reference to one or more such devices to individually or jointly execute a set (or multiple sets) of instructions to perform any one or more of the methodologies discussed herein. For example, control system may include a single control unit or a plurality of control units connected or otherwise communicatively coupled to each other, such that any performed function may be distributed between the control units as desired. Further, such devices may communicate with each other or other devices by various system architectures, such as directly or via a Controller Area Network (CAN) bus, etc.

The computer system 400 may comprise at least one computing device or electronic device capable of including firmware, hardware, and/or executing software instructions to implement the functionality described herein. The computer system 400 may include processing circuitry 402 (e.g., processing circuitry including one or more processor devices or control units), a memory 404, and a system bus 406. The computer system 400 may include at least one computing device having the processing circuitry 402. The system bus 406 provides an interface for system components including, but not limited to, the memory 404 and the processing circuitry 402. The processing circuitry 402 may include any number of hardware components for conducting data or signal processing or for executing computer code stored in memory 404. The processing circuitry 402 may, for example, include a general-purpose processor, an application specific processor, a Digital Signal Processor (DSP), an Application Specific Integrated Circuit (ASIC), a Field Programmable Gate Array (FPGA), a circuit containing processing components, a group of distributed processing components, a group of distributed computers configured for processing, or other programmable logic device, discrete gate or transistor logic, discrete hardware components, or any combination thereof designed to perform the functions described herein. The processing circuitry 402 may further include computer executable code that controls operation of the programmable device.

The system bus 406 may be any of several types of bus structures that may further interconnect to a memory bus (with or without a memory controller), a peripheral bus, and/or a local bus using any of a variety of bus architectures. The memory 404 may be one or more devices for storing data and/or computer code for completing or facilitating methods described herein. The memory 404 may include database components, object code components, script components, or other types of information structure for supporting the various activities herein. Any distributed or local memory device may be utilized with the systems and methods of this description. The memory 404 may be communicably connected to the processing circuitry 402 (e.g., via a circuit or any other wired, wireless, or network connection) and may include computer code for executing one or more processes described herein. The memory 404 may include non-volatile memory 408 (e.g., read-only memory (ROM), erasable programmable read-only memory (EPROM), electrically erasable programmable read-only memory (EEPROM), etc.), and volatile memory 410 (e.g., random-access memory (RAM)), or any other medium which can be used to carry or store desired program code in the form of machine-executable instructions or data structures and which can be accessed by a computer or other machine with processing circuitry 402. A basic input/output system (BIOS) 412 may be stored in the non-volatile memory 408 and can include the basic routines that help to transfer information between elements within the computer system 400.

The computer system 400 may further include or be coupled to a non-transitory computer-readable storage medium such as the storage device 414, which may comprise, for example, an internal or external hard disk drive (HDD) (e.g., enhanced integrated drive electronics (EIDE) or serial advanced technology attachment (SATA)), HDD (e.g., EIDE or SATA) for storage, flash memory, or the like. The storage device 414 and other drives associated with computer-readable media and computer-usable media may provide non-volatile storage of data, data structures, computer-executable instructions, and the like.

Computer-code which is hard or soft coded may be provided in the form of one or more modules. The module(s) can be implemented as software and/or hard-coded in circuitry to implement the functionality described herein in whole or in part. The modules may be stored in the storage device 414 and/or in the volatile memory 410, which may include an operating system 416 and/or one or more program modules 418. All or a portion of the examples disclosed herein may be implemented as a computer program 420 stored on a transitory or non-transitory computer-usable or computer-readable storage medium (e.g., single medium or multiple media), such as the storage device 414, which includes complex programming instructions (e.g., complex computer-readable program code) to cause the processing circuitry 402 to carry out actions described herein. Thus, the computer-readable program code of the computer program 420 can comprise software instructions for implementing the functionality of the examples described herein when executed by the processing circuitry 402. In some examples, the storage device 414 may be a computer program product (e.g., readable storage medium) storing the computer program 420 thereon, where at least a portion of a computer program 420 may be loadable (e.g., into a processor) for implementing the functionality of the examples described herein when executed by the processing circuitry 402. The processing circuitry 402 may serve as a controller or control system for the computer system 400 that is to implement the functionality described herein.

The computer system 400 may include an input device interface 422 configured to receive input and selections to be communicated to the computer system 400 when executing instructions, such as from a keyboard, mouse, touch-sensitive surface, etc. Such input devices may be connected to the processing circuitry 402 through the input device interface 422 coupled to the system bus 406 but can be connected through other interfaces, such as a parallel port, an Institute of Electrical and Electronic Engineers (IEEE) 1394 serial port, a Universal Serial Bus (USB) port, an IR interface, and the like. The computer system 400 may include an output device interface 424 configured to forward output, such as to a display, a video display unit (e.g., a liquid crystal display (LCD) or a cathode ray tube (CRT)). The computer system 400 may include a communications interface 426 suitable for communicating with a network as appropriate or desired.

The operational actions described in any of the exemplary aspects herein are described to provide examples and discussion. The actions may be performed by hardware components, may be embodied in machine-executable instructions to cause a processor to perform the actions, or may be performed by a combination of hardware and software. Although a specific order of method actions may be shown or described, the order of the actions may differ. In addition, two or more actions may be performed concurrently or with partial concurrence.

Example 1. A computer system comprising processing circuitry configured to: obtain a chassis voltage (V1) between a first traction voltage pole (A) and a chassis (P) of a vehicle (1); obtain a scheduled switching time (Ts) to switch from the first traction voltage pole (A) to the second traction voltage pole (B) in order to measure the chassis voltage (V2) between the second traction voltage pole (B) and the chassis (P) of the vehicle (1); determine a disturbance on the first or second traction voltage pole (A, B); adjust the scheduled switching time (Ts) and/or a corrective algorithm; and obtain a chassis voltage (V2) between the second traction voltage pole (B) and the chassis (P) of the vehicle (1) based on the adjusted switching time (Ts) and/or the corrective algorithm.

Example 2. The computer system of Example 1, wherein the processing circuitry is further configured to determine the disturbance as a scheduled disturbance or an occurring disturbance on the first or second traction voltage pole (A, B).

Example 3. The computer system of Example 1 or 2, wherein the processing circuitry is further configured to obtain a time request (Tr) for a predicted shift of the chassis voltage occurring at the scheduled switching time.

Example 4. The computer system of any of Examples 1-3, wherein the processing circuitry is further configured to: determine that the time request (Tr) for the predicted shift of the chassis voltage (V1) is within a predetermined time interval (Ti) relative the scheduled switching time (Ts), and adjust at least one of the scheduled switching time (Ts) and the time request (Tr) such that the time request (Tr) for the predicted shift of the chassis voltage (V1) is outside the predetermined time interval (Ti).

Example 5. The computer system of any of Examples 3-4, wherein the processing circuitry is further configured to: obtain the time request (Tr) for the predicted shift of the chassis voltage (V1) by obtaining a time request (Tr) for an electrical connection of a vehicle component (10) to the first traction voltage pole (A).

Example 6. The computer system of any of Examples 3-5, wherein the processing circuitry is further configured to: adjust at least one of the scheduled switching time (Ts) and the time request (Tr) by delaying the scheduled switching time (Ts).

Example 7. The computer system of any of Examples 3-6, wherein the processing circuitry is further configured to: adjust at least one of the scheduled switching time (Ts) and the time request (Tr) by delaying the electrical connection of a vehicle component (10) to the first traction voltage pole (A).

Example 8. The computer system of any of Examples 3-7, wherein the processing circuitry is further configured to: determine a time window (Tw), and adjust at least one of the scheduled switching time (Ts) and the time request (Tr) by effecting the switch from the first traction voltage pole (A) to a second traction voltage pole (B) and/or the electrical connection of a vehicle component (10) to the first traction voltage pole (A) within said time window.

Example 9. The computer system of any of Examples 3-8, wherein the processing circuitry is further configured to: determine that the chassis voltage (V1) is swinging; wherein the time request (Tr) for the predicted shift of the chassis voltage (V1) coincides with the swinging behavior of the chassis voltage (V1).

Example 10. The computer system of any of Examples 1-9, wherein the processing circuitry is further configured to: switch from the first traction voltage pole (A) to a second traction voltage pole (B) at a non-ideal shift of the obtained chassis voltage (V1); obtain a chassis voltage (V2) between a second traction voltage pole (B) and the chassis (P) of the vehicle (1); and correct the obtained chassis voltage (V2) between the second traction voltage pole (B) and the chassis (P) of the vehicle (1) based on the non-ideal shift of the obtained chassis voltage (V1).

Example 11. The computer system of Example 10, wherein the processing circuitry is further configured to: suppress the obtained chassis voltage (V2) between the second traction voltage pole (B) and the chassis (P) of the vehicle (1) based on the non-ideal shift of the obtained chassis voltage (V1).

Example 12. The computer system of any of Examples 1-11, wherein the processing circuitry is further configured to: determine an isolation resistance (IRA) between the first traction voltage pole (A) and the chassis (P) of the vehicle (1) based on the measured chassis voltage (V1), and determine an isolation resistance (IRB) between the second traction voltage pole (B) and the chassis (P) of the vehicle (1) based on the measured chassis voltage (V2).

Example 13. The computer system of Example 1, wherein the processing circuitry is further configured to: determine the disturbance as a scheduled disturbance or an occurring disturbance on the first or second traction voltage pole; obtain a time request for a predicted shift of the chassis voltage occurring at the scheduled switching time; determine that the time request (Tr) for the predicted shift of the chassis voltage (V1) is within a predetermined time interval (Ti) relative the scheduled switching time (Ts), and adjust at least one of the scheduled switching time (Ts) and the time request (Tr) such that the time request (Tr) for the predicted shift of the chassis voltage (V1) is outside the predetermined time interval (Ti) and wherein the time request (Tr) is synchronized with the chassis voltage (V1) being asymptotic: obtain the time request (Tr) for the predicted shift of the chassis voltage (V1) by obtaining a time request (Tr) for an electrical connection of a vehicle component (10) to the first traction voltage pole (A); adjust at least one of the scheduled switching time (Ts) and the time request (Tr) by delaying the scheduled switching time (Ts); adjust at least one of the scheduled switching time (Ts) and the time request (Tr) by delaying the electrical connection of a vehicle component (10) to the first traction voltage pole (A); determine a time window (Tw), and adjust at least one of the scheduled switching time (Ts) and the time request (Tr) by effecting the switch from the first traction voltage pole (A) to a second traction voltage pole (B) and/or the electrical connection of a vehicle component (10) to the first traction voltage pole (A) within said time window; determine that the chassis voltage (V1) is swinging; wherein the time request (Tr) for the predicted shift of the chassis voltage (V1) coincides with the swinging behavior of the chassis voltage (V1); switch from the first traction voltage pole (A) to a second traction voltage pole (B) at a non-ideal shift of the obtained chassis voltage (V1); obtain a chassis voltage (V2) between a second traction voltage pole (B) and the chassis (P) of the vehicle (1); and suppress the obtained chassis voltage (V2) between the second traction voltage pole (B) and the chassis (P) of the vehicle (1) based on the non-ideal shift of the obtained chassis voltage (V1); and determine an isolation resistance (IRA) between the first traction voltage pole (A) and the chassis (P) of the vehicle (1) based on the measured chassis voltage (V1), and determine an isolation resistance (IRB) between the second traction voltage pole (B) and the chassis (P) of the vehicle (1) based on the measured chassis voltage (V2).

Example 14. A vehicle comprising the computer system of any of Examples 1-13.

Example 15. The vehicle of Example 14, further comprising: a traction voltage bus (12) comprising a first traction voltage pole (A) and a second traction voltage pole (B), and an isolation resistance monitoring device (20) configured to monitor the isolation resistance (IRA, IRB) between the voltage bus (12) and a chassis (P) of the vehicle (1), and to selectively switch the connection between the first and second traction voltage poles (A, B).

Example 16. A computer-implemented method, comprising: obtaining, by processing circuitry of a computer system, a chassis voltage (V1) between a first traction voltage pole (A) and a chassis (P) of a vehicle (1); obtaining, by the processing circuitry, a scheduled switching time (Ts) to switch from the first traction voltage pole (A) to the second traction voltage pole (B) in order to measure the chassis voltage (V2) between the second traction voltage pole (B) and the chassis (P) of the vehicle (1); determining, by the processing circuitry, a disturbance on the first or second traction voltage pole; adjusting, by the processing circuitry, the scheduled switching time (Ts) and/or a corrective algorithm; and obtaining, by the processing circuitry, a chassis voltage (V2) between the second traction voltage pole (B) and the chassis (P) of the vehicle (1) based on the scheduled switching time (Ts) and/or the corrective algorithm.

Example 17. The method of Example 16, further comprising: obtaining a time request (Tr) for a predicted shift of the chassis voltage occurring at the scheduled switching time.

Example 18. The method of Example 17, further comprising: determining, by the processing circuitry, that the time request (Tr) for the predicted shift of the chassis voltage (V1) is within a predetermined time interval (Ti) relative the scheduled switching time (Ts), and adjusting, by the processing circuitry, at least one of the scheduled switching time (Ts) and the time request (Tr) such that the time request (Tr) for the predicted shift of the chassis voltage (V1) is outside the predetermined time interval (Ti).

Example 19. The method of any of Examples 17-18, further comprising: obtaining, by the processing circuitry, the time request (Tr) for the predicted shift of the chassis voltage (V1) by obtaining a time request (Tr) for an electrical connection of a vehicle component (10) to the first traction voltage pole (A).

Example 20. The method of any of Examples 17-19, further comprising: adjusting, by the processing circuitry, at least one of the scheduled switching time (Ts) and the time request (Tr) by delaying the scheduled switching time (Ts).

Example 21. The method of any of Examples 17-20, further comprising: adjusting, by the processing circuitry, at least one of the scheduled switching time (Ts) and the time request (Tr) by delaying the electrical connection of a vehicle component (10) to the first traction voltage pole (A).

Example 22. A computer program product comprising program code for performing, when executed by the processing circuitry, the method of any of Examples 16-22.

Example 23. A non-transitory computer-readable storage medium comprising instructions, which when executed by the processing circuitry, cause the processing circuitry to perform the method of any of Examples 16-22.

The terminology used herein is for the purpose of describing particular aspects only and is not intended to be limiting of the disclosure. As used herein, the singular forms "a," "an," and "the" are intended to include the plural forms as well, unless the context clearly indicates otherwise. As used herein, the term "and/or" includes any and all combinations of one or more of the associated listed items. It will be further understood that the terms "comprises," "comprising," "includes," and/or "including" when used herein specify the presence of stated features, integers, actions, steps, operations, elements, and/or components, but do not preclude the presence or addition of one or more other features, integers, actions, steps, operations, elements, components, and/or groups thereof.

It will be understood that, although the terms first, second, etc., may be used herein to describe various elements, these elements should not be limited by these terms. These terms are only used to distinguish one element from another. For example, a first element could be termed a second element, and, similarly, a second element could be termed a first element without departing from the scope of the present disclosure.

Relative terms such as "below" or "above" or "upper" or "lower" or "horizontal" or "vertical" may be used herein to describe a relationship of one element to another element as illustrated in the Figures. It will be understood that these terms and those discussed above are intended to encompass different orientations of the device in addition to the orientation depicted in the Figures. It will be understood that when an element is referred to as being "connected" or "coupled" to another element, it can be directly connected or coupled to the other element, or intervening elements may be present. In contrast, when an element is referred to as being "directly connected" or "directly coupled" to another element, there are no intervening elements present.

Unless otherwise defined, all terms (including technical and scientific terms) used herein have the same meaning as commonly understood by one of ordinary skill in the art to which this disclosure belongs. It will be further understood that terms used herein should be interpreted as having a meaning consistent with their meaning in the context of this specification and the relevant art and will not be interpreted in an idealized or overly formal sense unless expressly so defined herein.

It is to be understood that the present disclosure is not limited to the aspects described above and illustrated in the drawings; rather, the skilled person will recognize that many changes and modifications may be made within the scope of the present disclosure and appended claims. In the drawings and specification, there have been disclosed aspects for purposes of illustration only and not for purposes of limitation, the scope of the disclosure being set forth in the following claims.

1. A computer system comprising processing circuitry configured to:
obtain a chassis voltage between a first traction voltage pole and a chassis of a vehicle;
obtain a scheduled switching time to switch from the first traction voltage pole to the second traction voltage pole in order to measure the chassis voltage between the second traction voltage pole and the chassis of the vehicle;
determine a disturbance on the first or second traction voltage pole;
adjust the scheduled switching time and/or a corrective algorithm; and
obtain a chassis voltage between the second traction voltage pole and the chassis of the vehicle based on the adjusted scheduled switching time and/or the corrective algorithm.

2. The computer system of claim 1, wherein the processing circuitry is further configured to:
determine the disturbance as a scheduled disturbance or an occurring disturbance on the first or second traction voltage pole.

3. The computer system of claim 1, wherein the processing circuitry is further configured to:
obtain a time request for a predicted shift of the chassis voltage occurring at the scheduled switching time.

4. The computer system of claim 3, wherein the processing circuitry is further configured to:
determine that the time request for the predicted shift of the chassis voltage is within a predetermined time interval relative the scheduled switching time, and
adjust at least one of the scheduled switching time and the time request such that the time request for the predicted shift of the chassis voltage is outside the predetermined time interval.

5. The computer system of claim 3, wherein the processing circuitry is further configured to:
obtain the time request for the predicted shift of the chassis voltage by obtaining a time request for an electrical connection of a vehicle component to the first traction voltage pole.

6. The computer system of claim 3, wherein the processing circuitry is further configured to:
adjust at least one of the scheduled switching time and the time request by delaying the scheduled switching time, and/or
adjust at least one of the scheduled switching time and the time request by delaying the electrical connection of a vehicle component to the first traction voltage pole.

7. The computer system of claim 3, wherein the processing circuitry is further configured to:
adjust at least one of the scheduled switching time and the time request by delaying the electrical connection of a vehicle component to the first traction voltage pole.

8. The computer system of claim 3, wherein the processing circuitry is further configured to:
determine a time window, and
adjust at least one of the scheduled switching time and the time request by effecting the switch from the first traction voltage pole to a second traction voltage pole and/or the electrical connection of a vehicle component to the first traction voltage pole within said time window.

9. The computer system of claim 3, wherein the processing circuitry is further configured to:
determine that the chassis voltage is swinging; wherein
the time request for the predicted shift of the chassis voltage coincides with the swinging behavior of the chassis voltage.

10. The computer system of claim 1, wherein the processing circuitry is further configured to:
switch from the first traction voltage pole to a second traction voltage pole at a non-ideal shift of the obtained chassis voltage;
obtain a chassis voltage between a second traction voltage pole and the chassis of the vehicle; and
correct the obtained chassis voltage between the second traction voltage pole and the chassis of the vehicle based on the non-ideal shift of the obtained chassis voltage.

11. The computer system of claim 10, wherein the processing circuitry is further configured to:
suppress the obtained chassis voltage between the second traction voltage pole and the chassis of the vehicle based on the non-ideal shift of the obtained chassis voltage.

12. The computer system of claim 1, wherein the processing circuitry is further configured to:
determine an isolation resistance between the first traction voltage pole and the chassis of the vehicle based on the measured chassis voltage, and determine an isolation resistance between the second traction voltage pole and the chassis of the vehicle based on the measured chassis voltage.

13. The computer system of claim 1, wherein the processing circuitry is further configured to:
determine the disturbance as a scheduled disturbance or an occurring disturbance on the first or second voltage pole;
obtain a time request for a predicted shift of the chassis voltage occurring at the scheduled switching time;
determine that the time request for the predicted shift of the chassis voltage is within a predetermined time interval relative the scheduled switching time, and
adjust at least one of the scheduled switching time and the time request such that the time request for the predicted shift of the chassis voltage is outside the predetermined time interval and wherein the time request is synchronized with the chassis voltage being asymptotic:
obtain the time request for the predicted shift of the chassis voltage by obtaining a time request for an electrical connection of a vehicle component to the first traction voltage pole;
adjust at least one of the scheduled switching time and the time request by delaying the scheduled switching time;
adjust at least one of the scheduled switching time and the time request by delaying the electrical connection of a vehicle component to the first traction voltage pole;
determine a time window, and
adjust at least one of the scheduled switching time and the time request by effecting the switch from the first traction voltage pole to a second traction voltage pole and/or the electrical connection of a vehicle component to the first traction voltage pole within said time window;
determine that the chassis voltage is swinging; wherein
the time request for the predicted shift of the chassis voltage coincides with the swinging behavior of the chassis voltage;
switch from the first traction voltage pole to a second traction voltage pole at a non-ideal shift of the obtained chassis voltage;
obtain a chassis voltage between a second traction voltage pole and the chassis of the vehicle; and
suppress the obtained chassis voltage between the second traction voltage pole and the chassis of the vehicle based on the non-ideal shift of the obtained chassis voltage; and
determine an isolation resistance between the first traction voltage pole and the chassis of the vehicle based on the measured chassis voltage, and determine an isolation resistance between the second traction voltage pole and the chassis of the vehicle based on the measured chassis voltage.

14. A vehicle comprising the computer system of a claim 1.

15. The vehicle of claim 14, further comprising:
a traction voltage bus comprising a first traction voltage pole and a second traction voltage pole, and an isolation resistance monitoring device configured to monitor the isolation resistance between the voltage bus and a chassis of the vehicle, and to selectively switch the connection between the first and second traction voltage poles.

16. A computer-implemented method, comprising:
obtaining, by processing circuitry of a computer system, a chassis voltage between a first traction voltage pole and a chassis of a vehicle;
obtaining, by the processing circuitry, a scheduled switching time to switch from the first traction voltage pole to the second traction voltage pole in order to measure the chassis voltage between the second traction voltage pole and the chassis of the vehicle;
determining, by the processing circuitry, a disturbance on the first or second traction voltage pole;
adjusting, by the processing circuitry, the scheduled switching time and/or a corrective algorithm; and
obtaining, by the processing circuitry, a chassis voltage between the second traction voltage pole and the chassis of the vehicle based on the adjusted scheduled switching time and/or the corrective algorithm.

17. The method of claim 16, further comprising: obtaining a time request for a predicted shift of the chassis voltage occurring at the scheduled switching time.

18. The method of claim 17, further comprising: determining, by the processing circuitry, that the time request for the predicted shift of the chassis voltage is within a predetermined time interval relative the scheduled switching time, and adjusting, by the processing circuitry, at least one of the scheduled switching time and the time request such that the time request for the predicted shift of the chassis voltage is outside the predetermined time interval.

19. A computer program product comprising program code for performing, when executed by the processing circuitry, the method of claim 16.

20. A non-transitory computer-readable storage medium comprising instructions, which when executed by the processing circuitry, cause the processing circuitry to perform the method of claim 16.
